(19) United States
(12) Patent Application Publication
(10) Pub. No.: US 2025/0301609 A1
(43) Pub. Date: Sep. 25, 2025

(54) MAGNETIC HEAT DISSIPATION MODULE AND ELECTRONIC DEVICE

(71) Applicant: GIGA-BYTE TECHNOLOGY CO.,LTD., New Taipei City (TW)

(72) Inventors: Chih-Ming Lai, New Taipei City (TW); Hui-Shan Chou, New Taipei City (TW)

(73) Assignee: GIGA-BYTE TECHNOLOGY CO.,LTD., New Taipei City (TW)

(21) Appl. No.: 19/000,636

(22) Filed: Dec. 23, 2024

(30) Foreign Application Priority Data
Mar. 20, 2024 (TW) 113110253

(51) Int. Cl. H05K 7/20

(52) U.S. Cl. CPC H05K 7/2039

(57) ABSTRACT

A magnetic heat dissipation module includes a magnetic base and a heatsink. The magnetic base includes a base and a first magnet. The base includes a fixed part, an extension part standing from the fixed part, a positioning eave bent and extending from the extension part, and a groove located between the positioning eave and the fixed part. The first magnet is located at the fixed part. The heatsink includes a docking part, a heat dissipation part connected to the docking part, and a second magnet disposed on the docking part. The docking part includes a pivot end and an extending end adjacent to each other. When the heatsink is assembled to the magnetic base, the extending end of the heatsink is inserted into the groove obliquely, so that the second magnet is magnetically attracted to the first magnet, and the docking part is positioned to the fixed part.

### CROSS-REFERENCE TO RELATED APPLICATION

This application claims the priority benefit of Taiwan application serial no. 113110253, filed on Mar. 20, 2024. The entirety of the above-mentioned patent application is hereby incorporated by reference herein and made a part of this specification.

### BACKGROUND

### Technical Field

The disclosure relates to a heat dissipation module and an electronic device, and more particularly, to a magnetic heat dissipation module and an electronic device.

### Description of Related Art

Currently, most heatsinks disposed on a motherboard are fixed with screws. Such a fixing method requires manual alignment, which is quite inconvenient in assembly.

### SUMMARY

The disclosure provides a magnetic heat dissipation module that may be quickly aligned, disassembled, and fixed well and firmly.

The disclosure provides an electronic device, which has the above magnetic heat dissipation module.

A magnetic heat dissipation module in the disclosure includes a magnetic base and a heatsink detachably disposed on the magnetic base. The magnetic base includes a base and a first magnet. The base includes a fixed part, an extension part standing from the fixed part, a positioning eave bent and extending from the extension part, and a groove located between the positioning eave and the fixed part, and the first magnet is located at the fixed part. The heatsink includes a docking part, a heat dissipation part connected to the docking part, and a second magnet disposed on the docking part. The docking part includes a pivot end and an extending end adjacent to each other, and magnetic properties of the first magnet and the second magnet are different. When the heatsink is assembled to the magnetic base, the extending end of the heatsink is inserted into the groove obliquely, and the pivot end is rotated toward the fixed part along the positioning eave, so that the second magnet is magnetically attracted to the first magnet, and the docking part is positioned to the fixed part.

In an embodiment of the disclosure, the positioning eave is in an outward convex arc shape, and the pivot end is in a concave arc shape corresponding to the positioning eave.

In an embodiment of the disclosure, the positioning eave includes a concession recess away from the fixed part to avoid interference with the pivot end.

In an embodiment of the disclosure, the base further includes a positioning rib located in the groove and connected to the fixed part and the positioning eave, and the docking part further includes a positioning recess part corresponding to the positioning rib.

In an embodiment of the disclosure, the fixed part includes a plate body and a raised support structure protruding from a lower surface of the plate body.

In an embodiment of the disclosure, the plate body includes a notch recessed from an edge.

An electronic device in the disclosure includes a motherboard and the magnetic heat dissipation module. The motherboard includes a heat source. The fixed part is disposed on the motherboard, and is located next to the heat source. When the heatsink is assembled to the magnetic base, the heat dissipation part is thermally coupled to the heat source.

In an embodiment of the disclosure, the fixed part includes a plate body and a raised support structure protruding from a lower surface of the plate body. The motherboard includes a first electronic element. The raised support structure is abutted against the motherboard. The plate body is separated from the motherboard. The first electronic element is located between the plate body and the motherboard.

In an embodiment of the disclosure, the motherboard includes a second electronic element. The plate body includes a notch recessed from an edge. The second electronic element is located in the notch.

In an embodiment of the disclosure, the electronic device further includes a screwing member. The base further includes a positioning rib, and the screwing member passes through the motherboard and partially extends into the positioning rib, so that the magnetic base is fixed to the motherboard.

Based on the above, the first magnet of the magnetic base of the magnetic heat dissipation module in the disclosure is located at the fixed part of the base, and the second magnet of the heatsink is located on at docking part. The base further includes the positioning eave and the groove located between the positioning eave and the fixed part. When the heatsink is assembled to the magnetic base, the extending end of the heatsink is inserted into the groove of the magnetic base obliquely, and the pivot end of the heatsink is rotated toward the fixed part along the positioning eave of the magnetic base, so that the second magnet is magnetically attracted to the first magnet, and the docking part is positioned to the fixed part. Therefore, when the heatsink of the magnetic heat dissipation module in the disclosure is assembled to or disassembled from the magnetic base, it may be well guided by the outer contour of the positioning eave to easily complete disassembly and assembly, reducing a probability of damage to the elements on the motherboard during assembly. In addition, since the positioning eave provides a specific disassembly and assembly trajectory of the heatsink, the disassembly and assembly trajectory is, for example, different from magnetic attraction directions of the first magnet and the second magnet, which may effectively reduce a probability that the heatsink is easily detached from the magnetic base due to the vibration during the transportation of the electronic device. In addition, due to the attraction of the first magnet and the second magnet, it may achieve rapid alignment and fixation effects. The first magnet and the second magnet have different magnetic properties and provide greater magnetic attraction force, so that the heatsink may be well and firmly fixed on the magnetic base.

### BRIEF DESCRIPTION OF THE DRAWINGS

FIG. 1 is a schematic view of an electronic device according to an embodiment of the disclosure.

FIG. 2 is a schematic partial three-dimensional view of a heatsink in FIG. 1 lifted up.

FIG. 3 is a schematic view of the heatsink in FIG. 1 detached from a magnetic base from another perspective.

FIG. 4 is a schematic view of a back of the heatsink in FIG. 1.

FIGS. 5 and 6 are schematic cross-sectional views of a lifting process of the heatsink in

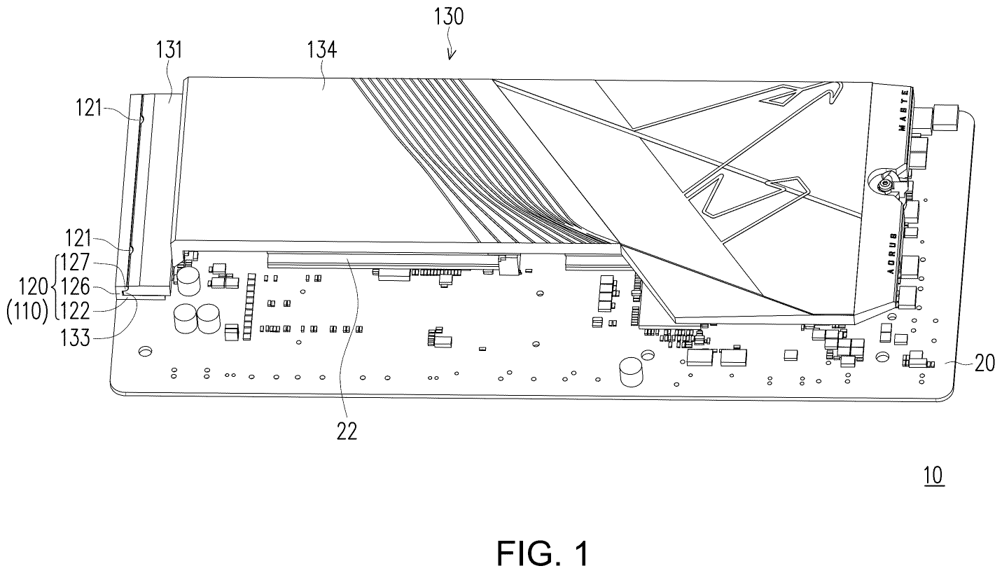

FIG. 1.

FIG. 7 is a schematic view of a back of a magnetic base in FIG. 1.

FIG. 8 is a schematic perspective view of the magnetic base in FIG. 1 on a motherboard.

FIG. 9 is a cross-sectional view of the magnetic base in FIG. 1 on a motherboard.

### DETAILED DESCRIPTION OF DISCLOSED EMBODIMENTS

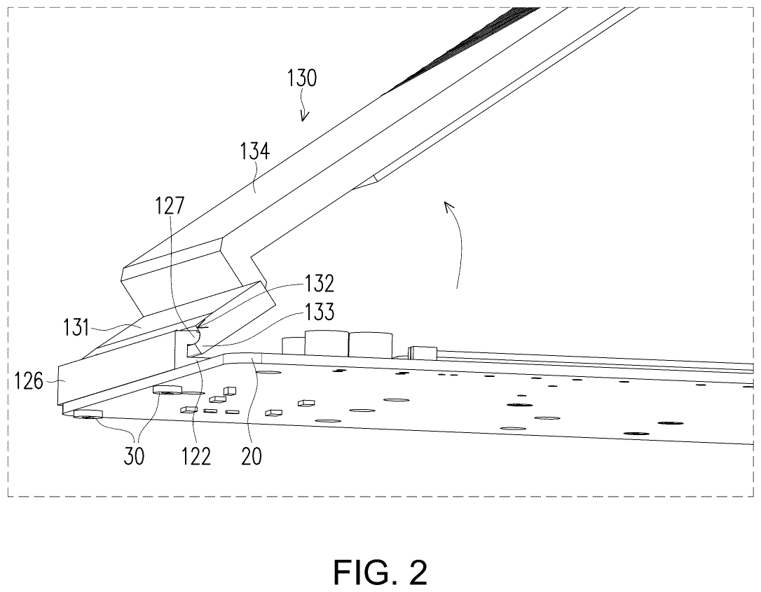

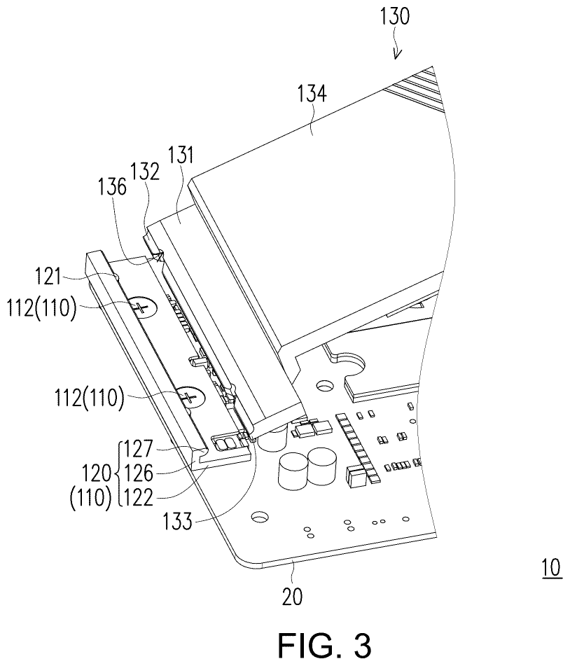

FIG. 1 is a schematic view of an electronic device according to an embodiment of the disclosure. FIG. 2 is a schematic partial three-dimensional view of a heatsink in FIG. 1 lifted up. FIG. 3 is a schematic view of the heatsink in FIG. 1 detached from a magnetic base from another perspective.

Referring to FIGS. 1 to 3, an electronic device 10 in this embodiment includes a motherboard 20 and a magnetic heat dissipation module 100. The motherboard 20 includes a heat source 22. The heat source 22 is, for example, a solid state drive (SSD), but a type of the heat source 22 is not limited thereto.

The magnetic heat dissipation module 100 in this embodiment includes a magnetic base 110 and a heatsink 130 detachably disposed on the magnetic base 110. The magnetic base 110 includes a base 120 and a first magnet 112 (FIG. 3). The first magnet 112 is located at a fixed part 122. As shown in FIG. 1, in this embodiment, the fixed part 122 is disposed on the motherboard 20, and is located next to the heat source 22.

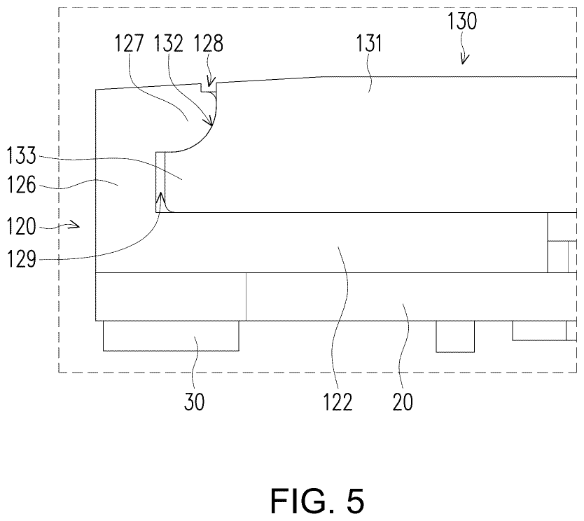

As shown in FIG. 3, the base 120 includes the fixed part 122, an extension part 126 standing from the fixed part 122, a positioning eave 127 bent and extending from the extension part 126, and a groove 129 (FIG. 5) located between the positioning eave 127 and the fixed part 122.

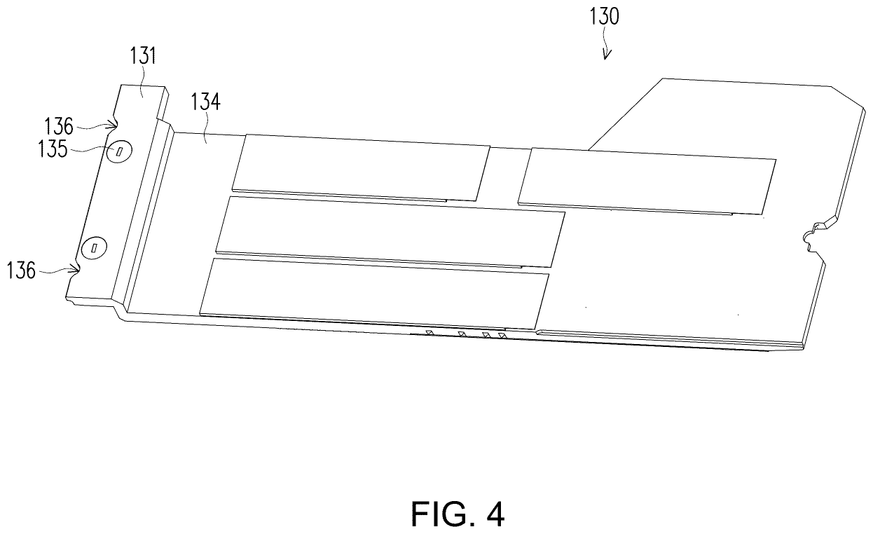

FIG. 4 is a schematic view of a back of the heatsink in FIG. 1. Referring to FIG. 4, the heatsink 130 includes a docking part 131, a heat dissipation part 134 connected to the docking part 131, and a second magnet 135 disposed on the docking part 131. In this embodiment, there is a height difference between the docking part 131 and the heat dissipation part 134, but a positional relationship between the docking part 131 and the heat dissipation part 134 is not limited thereto.

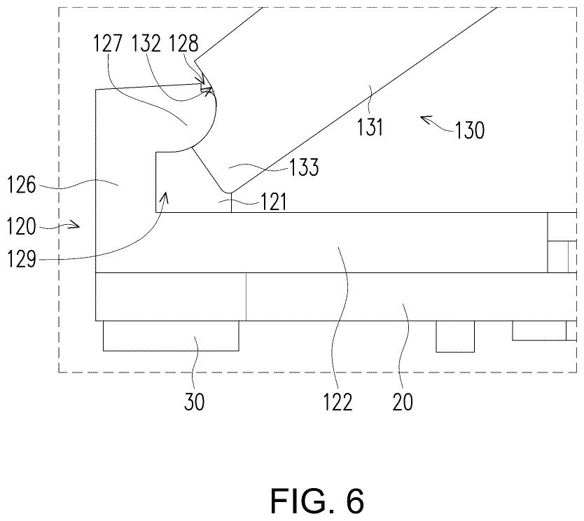

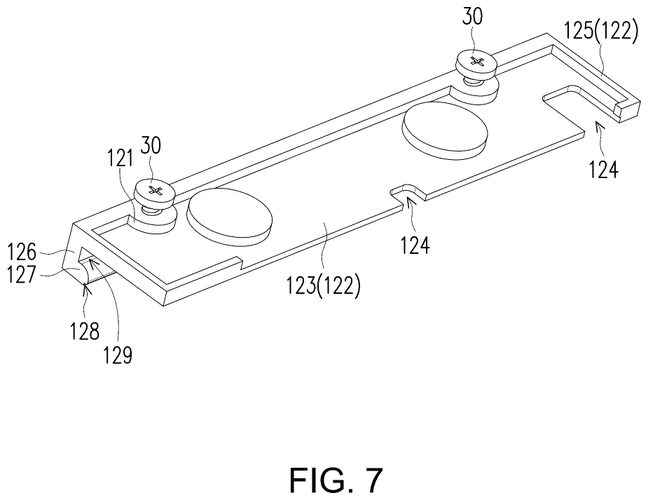

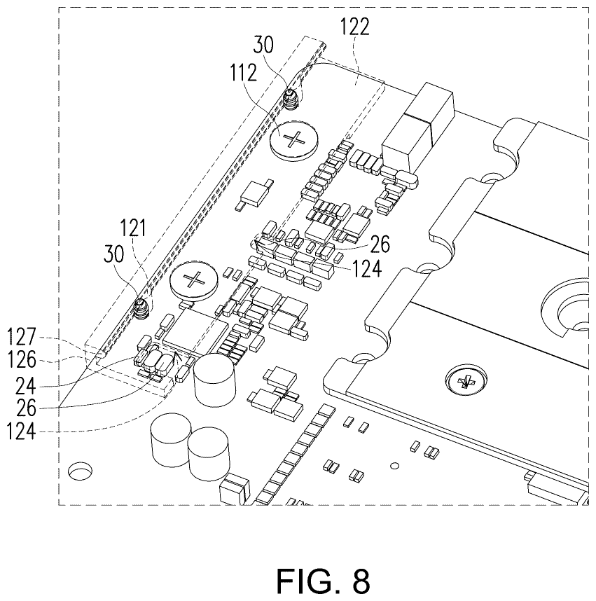

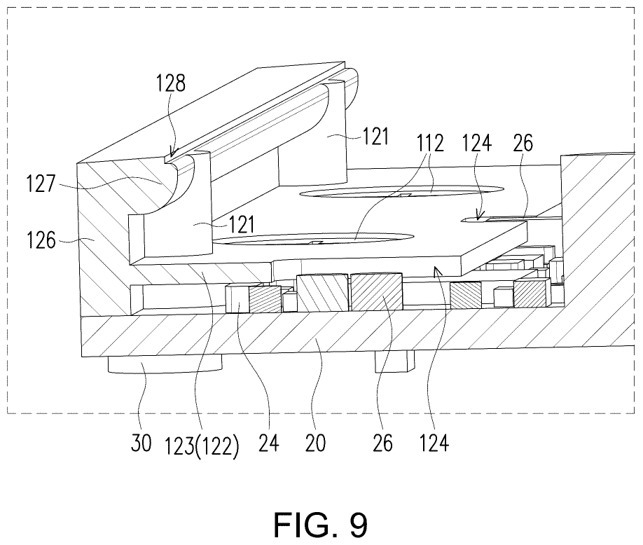

FIGS. 5 and 6 are schematic cross-sectional views of a lifting process of the heatsink in FIG. 1. Referring to FIGS. 5 and 6, in this embodiment, the positioning eave 127 of the base 120 of the magnetic base 110 are in an outward convex arc shape. The docking part 131 includes a pivot end 132 and an extending end 133 adjacent to each other. The pivot end 132 of the docking part 131 of the heatsink 130 is in a concave arc shape corresponding to the positioning eave 127. A shape of the positioning eave 127 matches the shape of the pivot end 132, so that the positioning eave 127 may provide guidance for the pivot end 132 during a rotation process.

Therefore, when the heatsink 130 is assembled to the magnetic base 110, the user only needs to insert the extending end 133 of the heatsink 130 into the groove 129 obliquely, the pivot end 132 of the heatsink 130 is abutted against the positioning eave 127 of the magnetic base 110, and the pivot end 132 is rotated toward (rotated downward) the fixed part 122 along the positioning eave 127. The heatsink 130 may be smoothly rotated downward to a position along an outer contour of the positioning eave 127, so that the second magnet 135 (FIG. 4) is magnetically attracted to the first magnet 112 (FIG. 3), and the docking part 131 is positioned to the fixed part 122, so that the heat dissipation part 134 (FIG. 1) is thermally coupled to the heat source 22 (FIG. 1).

In this embodiment, magnetic properties of the first magnet 112 and the second magnet 135 are different, thereby providing a greater magnetic attraction force, so that the heatsink 130 may be well and firmly fixed to the magnetic base 110.

In addition, since the heatsink 130 is rotated downward along the positioning eave 127 during an assembly process, the heatsink 130 may be prevented from damaging electronic elements on the motherboard 20 during installation, thereby increasing safety.

It should be noted that in this embodiment, a magnetic direction of the first magnet 112 and the second magnet 135 (a normal direction of the motherboard 20) is different from a rotation trajectory when the heatsink 130 is removed. Since the positioning eave 127 restricts the heatsink 130 from being rotated along the positioning eave 127 and then moving out of the groove 129 when disassembling, this design may prevent the electronic device 10 from being easily detached from the magnetic base 110 due to vibration during transportation.

In addition, according to FIG. 6, in this embodiment, the positioning eave 127 includes a concession recess 128 away from the fixed part 122 to avoid interference with the pivot end, so that the heatsink 130 may be rotated smoothly.

FIG. 7 is a schematic view of a back of a magnetic base in FIG. 1. Referring to FIG. 7, in this embodiment, the fixed part 122 of the base 120 of the magnetic base 110 includes a plate body 123 and a raised support structure 125 protruding from a lower surface of the plate body 123. The raised support structure 125 is, for example, located at multiple edges of the plate body 123, but the disclosure is not limited thereto. The raised support structure 125 is used to abut against the motherboard 20 (FIG. 9), so that the plate body 123 is separated from the motherboard 20.

FIG. 8 is a schematic perspective view of the magnetic base in FIG. 1 on a motherboard. FIG. 9 is a cross-sectional view of the magnetic base in FIG. 1 on a motherboard. Referring to FIGS. 8 and 9, the motherboard 20 (FIG. 9) includes a first electronic element 24. In this embodiment, a height of the first electronic element 24 is less than a distance between the plate body 123 and the motherboard 20. Therefore, the first electronic element 24 may be disposed at a position of the motherboard 20 below the plate body 123.

That is to say, the raised support structure 125 is used to heighten the plate body 123, which may avoid interference between the first electronic element 24 on the motherboard 20 and the plate body 123. Therefore, the motherboard 20 may still be provided with the first electronic element 24 in a position covered by the plate body 123, thereby increasing flexibility of a circuit layout of the motherboard 20.

In addition, the plate body 123 includes a notch 124 recessed from the edge. The motherboard 20 includes a second electronic element 26. The second electronic element 26 is located in the notch 124 of the plate body 123 recessed from the edge. In this embodiment, a height of the second electronic element 26 is greater than the distance between the plate body 123 and the motherboard 20. Therefore, the notch 124 disposed on the plate body 123 may prevent the second electronic element 26 on the motherboard 20 from being restricted by a height of the plate body 123, thereby increasing the flexibility of the circuit layout of the motherboard 20.

Furthermore, as shown in FIG. 9, the base 120 further includes a positioning rib 121 located in the groove 129 (FIG. 6) and connected to the fixed part 122 and the positioning eave 127. As shown in FIG. 3, the docking part 131 of the heatsink 130 further includes a positioning recess part 136 corresponding to the positioning rib 121.

When the heatsink 130 is assembled to the magnetic base 110, the positioning recess part 136 of the heatsink 130 is docked to the positioning rib 121 of the base 120 to be positioned in a horizontal direction. The extending end 133 of the heatsink 130 is located in the groove 129 of the base 120 to be positioned in a vertical direction. The first magnet 112 and the second magnet 135 have different magnetic poles and have greater magnetic attraction force. Therefore, the heatsink 130 may be well aligned and firmly fixed to the magnetic base 110 without tools.

In addition, the electronic device 10 further includes a screwing member 30 (FIG. 8). In this embodiment, the magnetic base 110 is fixed to the motherboard 20 in a screwing manner through the screwing member 30. The screwing member 30 passes through the motherboard 20 and partially extends into the positioning rib 121 to fix the magnetic base 110 to the motherboard 20.

It should be noted that in this embodiment, in addition to an outer surface of the positioning rib 121 having a function of positioning the heatsink 130, an inside of the positioning rib 121 also provides a space for the screwing member 30 to lock. Therefore, both the outer surface of the positioning rib 121 and the inner space are well utilized.

Specifically, in this embodiment, since the positioning rib 121 is combined with the raised support structure 125 abutted against the motherboard 20, the motherboard 20 is not provided with a protruding element at a position corresponding to the positioning rib 121 to avoid being pressed and damaged. Therefore, in this embodiment, with the restriction that the motherboard 20 is not provided with the element at the position corresponding to the positioning rib 121, the motherboard 20 is further provided with a through hole at the position corresponding to the positioning rib 121 for the screwing member 30 to pass through. In this way, a designer does not need to dispose the through hole for the screwing member 30 to pass through in other positions of the motherboard 20. This design may save the space on the motherboard 20 and increase the flexibility of the circuit layout of the motherboard 20.

Based on the above, the first magnet of the magnetic base of the magnetic heat dissipation module in the disclosure is located at the fixed part of the base, and the second magnet of the heatsink is located on at docking part. The base further includes the positioning eave and the groove located between the positioning eave and the fixed part. When the heatsink is to be assembled to the magnetic base, the extending end of the heatsink is inserted into the groove of the magnetic base obliquely, and the pivot end of the heatsink is rotated downward along the positioning eave of the magnetic base, so that the second magnet is magnetically attracted to the first magnet. Therefore, when the heatsink of the magnetic heat dissipation module in the disclosure is assembled to or disassembled from the magnetic base, it may be well guided by the outer contour of the positioning eave to easily complete disassembly and assembly, reducing a probability of damage to the elements on the motherboard during assembly. In addition, since the positioning eave provides a specific disassembly and assembly trajectory of the heatsink, the disassembly and assembly trajectory is, for example, different from magnetic attraction directions of the first magnet and the second magnet, which may effectively reduce a probability that the heatsink is easily detached from the magnetic base due to the vibration during the transportation of the electronic device. In addition, due to the attraction of the first magnet and the second magnet, it may achieve rapid alignment and fixation effects. The first magnet and the second magnet have different magnetic properties and provide greater magnetic attraction force, so that the heatsink may be well and firmly fixed on the magnetic base.

What is claimed is:

1. A magnetic heat dissipation module, comprising:
a magnetic base comprising a base and a first magnet, wherein the base comprises a fixed part, an extension part standing from the fixed part, a positioning eave bent and extending from the extension part, and a groove located between the positioning eave and the fixed part, and the first magnet is located at the fixed part; and
a heatsink detachably disposed on the magnetic base, wherein the heatsink comprises a docking part, a heat dissipation part connected to the docking part, and a second magnet disposed on the docking part, the docking part comprises a pivot end and an extending end adjacent to each other, and magnetic properties of the first magnet and the second magnet are different,
when the heatsink is assembled to the magnetic base, the extending end of the heatsink is inserted into the groove obliquely, and the pivot end is rotated toward the fixed part along the positioning eave, so that the second magnet is magnetically attracted to the first magnet, and the docking part is positioned to the fixed part.

2. The magnetic heat dissipation module according to claim 1, wherein the positioning eave is in an outward convex arc shape, and the pivot end is in a concave arc shape corresponding to the positioning eave.

3. The magnetic heat dissipation module according to claim 1, wherein the positioning eave comprises a concession recess away from the fixed part to avoid interference with the pivot end.

4. The magnetic heat dissipation module according to claim 1, wherein the base further comprises a positioning rib located in the groove and connected to the fixed part and the positioning eave, and the docking part further comprises a positioning recess part corresponding to the positioning rib.

5. The magnetic heat dissipation module according to claim 1, wherein the fixed part comprises a plate body and a raised support structure protruding from a lower surface of the plate body.

6. The magnetic heat dissipation module according to claim 5, wherein the plate body comprises a notch recessed from an edge.

7. An electronic device, comprising:
a motherboard comprising a heat source; and
the magnetic heat dissipation module according to claim 1, wherein the fixed part is disposed on the motherboard and is located next to the heat source, and when the heatsink is assembled to the magnetic base, the heat dissipation part is thermally coupled to the heat source.

8. The electronic device according to claim 7, wherein the fixed part comprises a plate body and a raised support structure protruding from a lower surface of the plate body, the motherboard comprises a first electronic element, the raised support structure is abutted against the motherboard, the plate body is separated from the motherboard, and the first electronic element is located between the plate body and the motherboard.

9. The electronic device according to claim 8, wherein the motherboard comprises a second electronic element, the plate body comprises a notch recessed from an edge, and the second electronic element is located in the notch.

10. The electronic device according to claim 7, further comprising a screwing member, wherein the base further comprises a positioning rib, and the screwing member passes through the motherboard and partially extends into the positioning rib, so that the magnetic base is fixed to the motherboard.

11. An electronic device, comprising:
a motherboard comprising a heat source; and
the magnetic heat dissipation module according to claim 2, wherein the fixed part is disposed on the motherboard and is located next to the heat source, and when the heatsink is assembled to the magnetic base, the heat dissipation part is thermally coupled to the heat source.

12. The electronic device according to claim 11, wherein the fixed part comprises a plate body and a raised support structure protruding from a lower surface of the plate body, the motherboard comprises a first electronic element, the raised support structure is abutted against the motherboard, the plate body is separated from the motherboard, and the first electronic element is located between the plate body and the motherboard.

13. The electronic device according to claim 12, wherein the motherboard comprises a second electronic element, the plate body comprises a notch recessed from an edge, and the second electronic element is located in the notch.

14. The electronic device according to claim 11, further comprising a screwing member, wherein the base further comprises a positioning rib, and the screwing member passes through the motherboard and partially extends into the positioning rib, so that the magnetic base is fixed to the motherboard.

15. An electronic device, comprising:
a motherboard comprising a heat source; and
the magnetic heat dissipation module according to claim 3, wherein the fixed part is disposed on the motherboard and is located next to the heat source, and when the heatsink is assembled to the magnetic base, the heat dissipation part is thermally coupled to the heat source.

16. The electronic device according to claim 15, wherein the fixed part comprises a plate body and a raised support structure protruding from a lower surface of the plate body, the motherboard comprises a first electronic element, the raised support structure is abutted against the motherboard, the plate body is separated from the motherboard, and the first electronic element is located between the plate body and the motherboard.

17. The electronic device according to claim 16, wherein the motherboard comprises a second electronic element, the plate body comprises a notch recessed from an edge, and the second electronic element is located in the notch.

18. The electronic device according to claim 15, further comprising a screwing member, wherein the base further comprises a positioning rib, and the screwing member passes through the motherboard and partially extends into the positioning rib, so that the magnetic base is fixed to the motherboard.
